(19) United States
(12) Patent Application Publication
(10) Pub. No.: US 2016/0057897 A1
(43) Pub. Date: Feb. 25, 2016

(54) Shielding Can With Internal Magnetic Shielding Layer

(71) Applicant: Apple Inc., Cupertino, CA (US)

(72) Inventors: Shayan Malek, San Jose, CA (US); James B. Smith, Los Gatos, CA (US); Gregory N. Stephens, Sunnyvale, CA (US)

(21) Appl. No.: 14/805,780

(22) Filed: Jul. 22, 2015

Related U.S. Application Data
(60) Provisional application No. 62/040,956, filed on Aug. 22, 2014.

(51) Int. Cl. H05K 9/00

(52) U.S. Cl. CPC H05K 9/0024

(57) ABSTRACT

An electronic device may have electrical components mounted on substrates such as printed circuits. The electrical components may include magnetic components such as inductors. A metal shielding can may be provided with a magnetic shielding layer to shield the magnetic components. The magnetic shielding layer may be formed on an inner surface of the metal shielding can. The magnetic shielding layer may include a ferromagnetic layer that is attached to the inner surface by a layer of adhesive. An insulating coating may be formed on the lower surface of the ferromagnetic layer to prevent shorts. An insulating layer for the lower surface of the ferromagnetic layer may be formed form a layer of polymer that is attached to the ferromagnetic layer with adhesive. The shielding can with magnetic shielding may withstand solder reflow temperatures, allowing the shielding can to be soldered to a printed circuit to shield an electrical component.

This application claims the benefit of provisional patent application No. 62/040,956, filed Aug. 22, 2014, which is hereby incorporated by reference herein in its entirety.

### BACKGROUND

This relates generally to electronic devices with electronic components and, more particularly, to structures for electromagnetically shielding electromagnetic components.

Electronic devices typically include printed circuit boards and other substrates to which electronic components are mounted. To prevent interference between components, sensitive components and components that are prone to emitting electromagnetic interference signals may be covered with metal shielding cans. The edges of a metal shielding can may be soldered to a printed circuit board to ground the shielding can. This type of approach may be used to prevent radio-frequency interference between circuits in an electronic device.

Some components such as inductors and other magnetic components produce large magnetic fields. To suppress interference from these magnetic fields, a magnetic shielding layer may be attached to the outer surface of a metal shielding can. The magnetic shielding layer contains a layer of ferromagnetic material sandwiched between a polyethyleneterephthalate carrier film and a layer of acrylic adhesive. The magnetic shielding layer helps suppress magnetic field signals that might otherwise affect nearby components, but adds undesired thickness to the shielding can. The carrier film and acrylic materials are also generally not compatible with the temperatures used for reflowing the solder that is used in attaching the edges of the metal shielding cans to the printed circuit board. As a result, the magnetic shielding layer cannot be attached to the metal shielding can until all printed circuit board soldering operations have been completed.

These restrictions pose challenges, particularly when it is desired to shield magnetic components in electronic devices in which space is scare such as portable electronic devices and when mounting shielding cans to printed circuits using solder.

It would therefore be desirable to be able to provide improved shielding cans such as shielding cans for shielding magnetic components.

### SUMMARY

An electronic device may have electrical components mounted on substrates such as printed circuits. The electrical components may include magnetic components such as inductors. A metal shielding can may be provided with a magnetic shielding layer to shield the magnetic components. The magnetic shielding layer may be formed on an inner surface of the metal shielding can. The magnetic shielding layer may include a ferromagnetic layer that is attached to the inner surface by a layer of adhesive. An insulating coating may be formed on the lower surface of the ferromagnetic layer to prevent shorts. An insulating layer for the lower surface of the ferromagnetic layer may be formed form a layer of polymer that is attached to the ferromagnetic layer with adhesive. The shielding can with magnetic shielding may withstand solder reflow temperatures, allowing the shielding can and internal magnetic shielding to be soldered to a printed circuit to shield an electrical component.

### BRIEF DESCRIPTION OF THE DRAWINGS

FIG. 1 is a diagram of an illustrative electronic device of the type that may have magnetic components shielded by shielding cans with magnetic shielding layers in accordance with an embodiment.

FIG. 2 is a cross-sectional diagram of an illustrative shielding can with magnetic shielding capabilities in accordance with an embodiment.

FIGS. 3 and 4 are cross-sectional side views of illustrative magnetic shielding layers that may be used in the interior of the shielding can of FIG. 2 in accordance with an embodiment.

FIG. 5 is an exploded perspective view of the underside of an illustrative shielding can with magnetic shielding capabilities in accordance with an embodiment.

FIG. 6 is a perspective view of a portion of the illustrative shielding can of FIG. 5 following attachment of a magnetic shielding layer to the inner surface of a metal shielding can structure in accordance with an embodiment.

FIG. 7 is a cross-sectional side view of an illustrative electronic device that has been provided with components covered with shielding cans in accordance with an embodiment.

### DETAILED DESCRIPTION

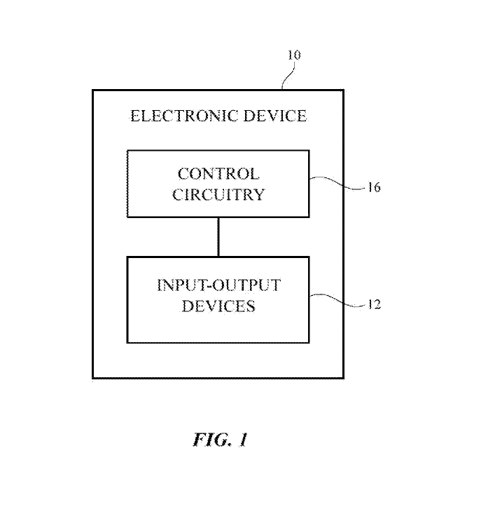

An illustrative electronic device of the type that may be provided with shielding cans such as shielding cans with magnetic shielding capabilities is shown in FIG. 1. As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays. Devices 12 may, for example, include a touch screen display that includes a touch sensor for gathering touch input from a user or a display that is insensitive to touch. A touch sensor for a touch screen display may be based on an array of capacitive touch sensor electrodes, acoustic touch sensor structures, resistive touch components, force-based touch sensor structures, a light-based touch sensor, or other suitable touch sensor arrangements.

Control circuitry 16 may be used to run software on device 10 such as operating system code and applications. During operation of device 10, the software running on control circuitry 16 may display images on the display.

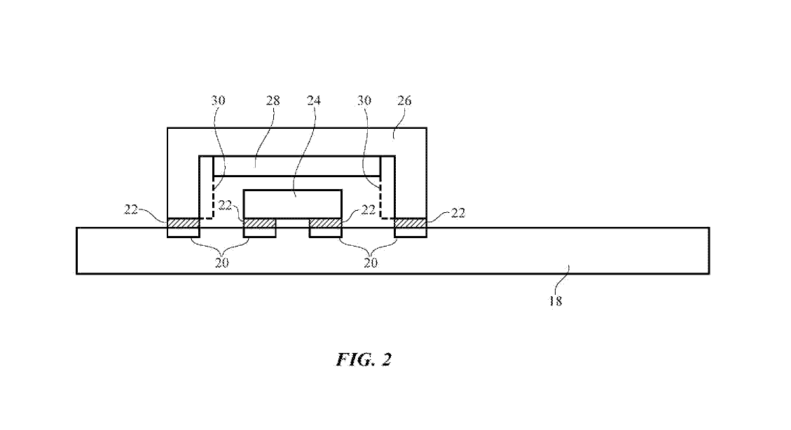

Device 10 (e.g., input-output devices 12 and control circuitry 16) may include electrical components such as electrical component 24 of FIG. 2. Electrical component 24 may be mounted on a substrate such as printed circuit 18. Printed circuit 18 may be a rigid printed circuit board (e.g., a printed circuit board formed from a fiberglass-filled epoxy substrate or other rigid printed circuit board material) or may be a flexible printed circuit (e.g., a printed circuit formed from a flexible layer of polyimide or a flexible sheet of other polymer material). Solder 22 may be used to mount electrical component 24 to metal traces 20 in printed circuit 18. Solder 22 may also be used to mount metal shielding can 26 to printed circuit 18. Metal shielding can 26 may have a planar upper wall surrounded by four vertical walls (i.e., shielding can 26 may have a rectangular shape when viewed from above). Shield cans with other shapes may also be used. The use of a rectangular shielding can configuration for shielding can 26 of FIG. 2 is merely illustrative.

Component 24 may be an inductor or other magnetic component that produces magnetic fields during operation. To magnetically shield component 24 and thereby suppress emission of these magnetic fields, magnetic shielding layer 28 may be formed on the inner surface of shielding can 26. For example, magnetic shielding layer 28 may be attached to the planar inner surface of the top of shielding can 26. Magnetic shielding layer 28 may also include portions that run along the inner surfaces of the sidewalls of can 26 (see, e.g., optional magnetic shielding layer portions 30).

Magnetic shielding layer 28 may be formed from materials that can withstand solder reflow temperatures. For example, magnetic shielding layer 28 may be formed from materials that do not degrade when exposed to temperatures of 250° C. (or other suitable elevated temperatures such as temperatures above 200° C., temperatures above 225° C., etc.). These temperatures can be used to reflow solder paste on printed circuit 18 to form solder joints 22.

The thickness of layer 28 may be about 30 microns, less than 30 microns, less than 50 microns, 5-40 microns, or other suitable thickness. These thicknesses may be relatively small compared with conventional magnetic shield tapes and may help reduce the vertical dimension (height) of the shield structures.

Because magnetic shielding layer 28 is formed from material that is compatible with solder reflow temperatures, shielding layer 28 may be formed on can 26 before can 26 is soldered to printed circuit 18 using solder 22. During the soldering process, can 26 and layer 28 will be subjected to elevated soldering temperatures, but shielding layer 28 will not be damaged.

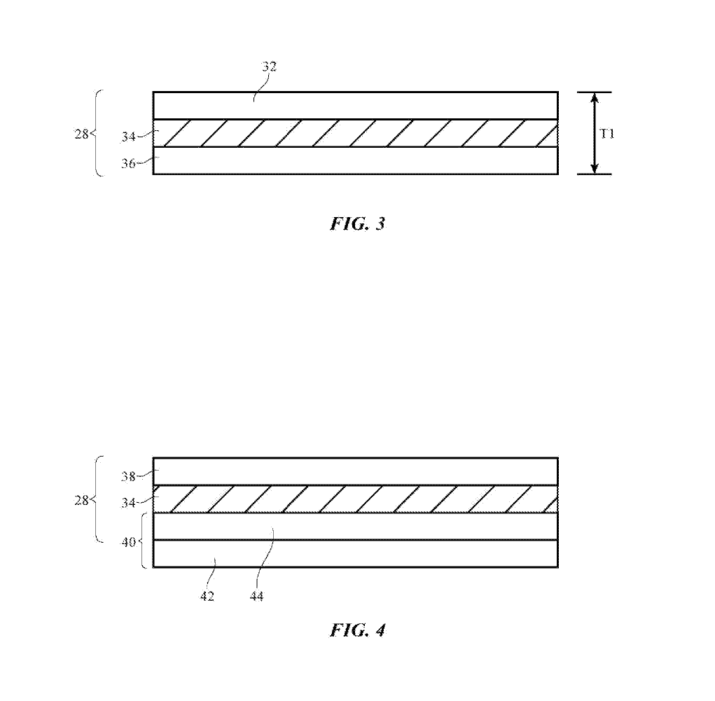

Illustrative layers of material that may be used to form magnetic shielding layer 28 are shown in the cross-sectional diagrams of FIGS. 3 and 4.

In the example of FIG. 3, magnetic shielding layer 28 has adhesive layer 32, magnetic shielding layer 34, and insulating layer 36. Adhesive layer 32 may be formed from an adhesive material such as silicone adhesive or other adhesive that can withstand elevated solder reflow temperatures. Magnetic shielding layer 34 may be a ferromagnetic material (e.g., a ferromagnetic alloy or other magnetic material with a high magnetic permeability and ability to magnetically shield component 24). The thickness of magnetic shielding layer 34 may be 20 microns, 10-30 microns, less than 40 microns, or more than 5 microns (as examples). Insulating layer 36 may be an inorganic layer (e.g., a layer of silicon oxide, silicon nitride, metal oxide, etc.) or may be a polymer layer. Insulating layer 36 may be deposited using physical vapor deposition, chemical vapor deposition, or other deposition techniques. The total thickness T1 of layer 28 of FIG. 3 may be less than 40 microns, less than 30 microns, 10-50 microns, or more than 20 microns (as examples).

FIG. 4 is a cross-sectional side view of another illustrative configuration that may be used to form magnetic shielding layer 28. In the configuration of FIG. 4, shielding layer 28 includes adhesive layer 38, magnetic shielding layer 34 (e.g., a ferromagnetic material for providing magnetic shielding), and dielectric layer 40. Layer 40 may be a layer of insulating tape having an adhesive layer such as layer 44 and a polymer carrier layer such as layer 42. Layers 44 and 42 may also be applied separately to layer 28, if desired.

The total thickness of layer 28 of FIG. 4 may be less than 40 microns, less than 30 microns, 10-50 microns, or more than 20 microns (as examples). The presence of a polymer layer such as polyimide layer 42 or other insulating layer may help enhance the ability of layer 28 to withstand scratches when contacted by components 24.

Adhesive layers 38 and 44 may be layers of silicone adhesive or other adhesive that is compatible with elevated solder reflow temperatures. Polymer layer 42 may be a layer of polyimide or other polymer layer that is resistant to scratching and that is compatible with elevated solder reflow temperatures.

Using adhesive layers 32 and 38, magnetic shielding layers 28 may be attached to the inner surface of the upper planar wall of metal shielding can 26.

The presence of insulating material such as layers 36 and 42 between magnetic material 34 and the upper portions of component 24 may help prevent undesired short circuits (e.g., shorts between component 24 and shield 26).

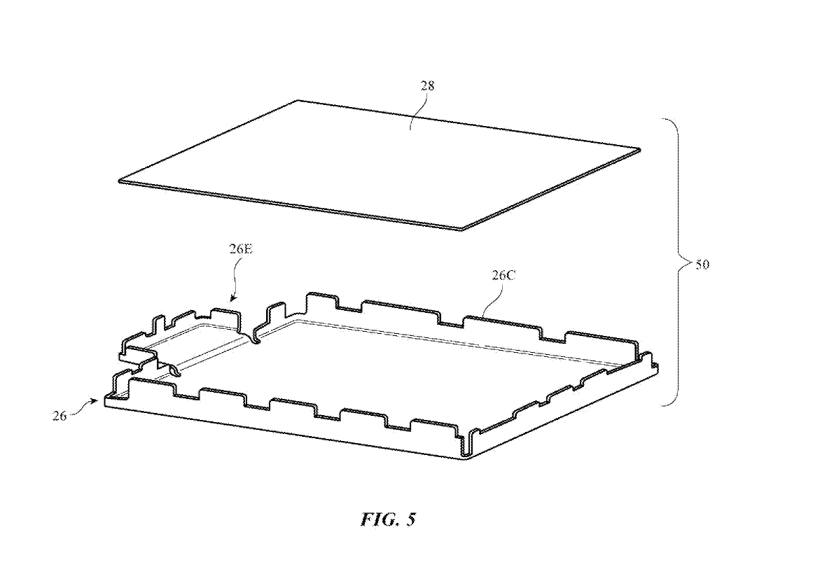

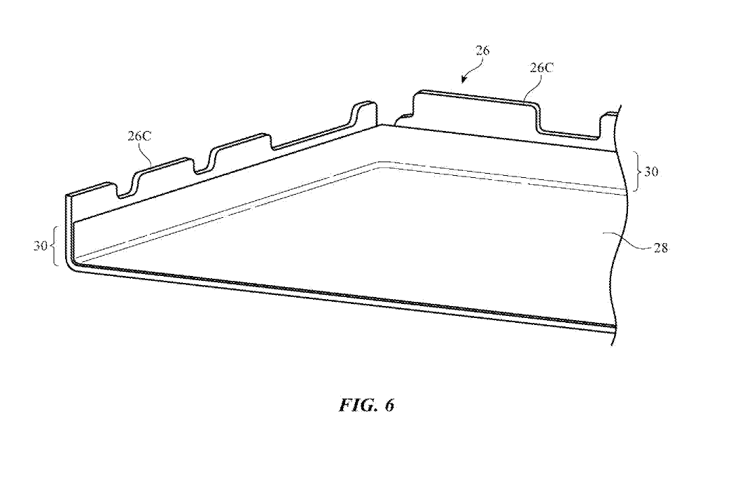

FIG. 5 is an exploded perspective view of the underside of an illustrative shielding can with magnetic shielding capabilities. As shown in the example of FIG. 5, metal shielding can 26 may have a rectangular shape, may have a rectangular shape with a protruding portion such as portion 26E of FIG. 5, may have smooth sidewalls, may have castellated sidewalls such as sidewalls 26C, or may have other suitable shapes. Magnetic shielding layer 28 may be received within the interior of shielding can structure 26. If desired, magnetic shielding layer 28 may have portions such as portions 30 that are attached to sidewalls 26C, as shown in FIG. 6.

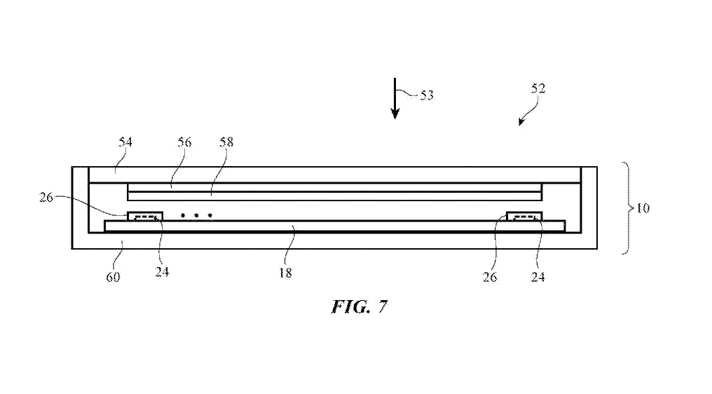

FIG. 7 is a cross-sectional side view of an illustrative electronic device such as electronic device 10 of FIG. 1 that has been provided with magnetically shielded inductors and other magnetically shielded components. As shown in FIG. 7, electronic device 10 may include a housing such as housing 60. Housing 60 may be formed from plastic, metal, glass, ceramic, carbon-fiber composites, fiberglass, and other fiber composites, and/or other materials. Components such as display 52 may be mounted in device housing 60.

Display 52 may include a cover layer such as display cover layer 54. Cover layer 54 may be formed from a clear material such as glass, transparent plastic, sapphire or other crystalline materials, transparent ceramic, other materials, or combinations of these materials. Cover layer 54 may be formed from a single layer of material or multiple sublayers. Cover layer 54 of FIG. 7 has planar upper and lower surfaces and may have a rectangular footprint (i.e., a rectangular outline when viewed from direction 53). If desired, cover layer 54 may have a curved profile and/or other shapes.

A touch sensor such a touch sensor 56 and display such as display module 58 or other display layers may be mounted within device 10 under display cover layer 54. Touch sensor 56 may be a capacitive touch sensor having an array of indium tin oxide electrodes or other transparent electrodes or may be a touch sensor formed using other touch technologies (e.g., force touch, resistive touch, acoustic touch, etc.). Capacitive touch sensor electrodes and associated touch sensor processing circuitry in touch sensor 56 may be sensitive to electromagnetic interference, so shielding components in device 10 with magnetic shielding may help reduce undesired noise in touch sensor 56.

Touch sensor 56 may be interposed between display module 58 and display cover layer 54. Display module 58 may be an organic light-emitting diode display, may be a liquid crystal display, or may include one or more display layers forming other types of display.

Electrical components 24 may be mounted in the interior of device 10. For example, electrical components 24 may be mounted on one or more substrates such as printed circuit 18. To ensure proper operation of touch sensor 56 and other circuitry in device 10, electrical components 24 may be provided with shield cans 26. Shield cans 26 may be lined with a layer of magnetic material such as magnetic shielding layer 28 to block magnetic interference.

Electrical components 24 may include integrated circuits, sensors, and other circuitry (see, e.g., control circuitry 16 and input-output devices 12 of FIG. 1). Electrical components 24 may include inductors and other circuitry that has the potential to generate electromagnetic interference (e.g., time varying magnetic fields) during operation. Through the use of magnetic shielding layer 28 in shield cans 26, this electromagnetic interference can be suppressed. As a result, less interference will be coupled into overlapping components such as touch sensor 56, display module 58 and/or other portions of display 52 and less interference will be coupled into other components 24.

The foregoing is merely illustrative and various modifications can be made by those skilled in the art without departing from the scope and spirit of the described embodiments. The foregoing embodiments may be implemented individually or in any combination.

What is claimed is:

1. A shielding can, comprising:
a metal shielding can structure having opposing inner and outer surfaces; and
a magnetic shielding layer on the inner surface.

2. The shielding can defined in claim 1 wherein the magnetic shielding layer comprises:
a ferromagnetic shielding layer; and
a layer of adhesive that attaches the ferromagnetic shielding layer to the inner surface.

3. The shielding can defined in claim 2 further comprising an insulating coating on the ferromagnetic shielding layer.

4. The shielding can defined in claim 3 wherein the layer of adhesive comprises silicone.

5. The shielding can defined in claim 1 wherein the magnetic shielding layer comprises:
a ferromagnetic shielding layer;
a layer of adhesive that attaches the ferromagnetic shielding layer to the inner surface; and
a polyimide layer that is attached to the ferromagnetic shielding layer with adhesive.

6. The shielding can defined in claim 5 wherein the ferromagnetic shielding layer has a thickness of less than 40 microns.

7. The shielding can defined in claim 6 wherein the ferromagnetic shielding layer has a thickness of at least 5 microns.

8. The shielding can defined in claim 1 wherein the magnetic shielding layer comprises:
a ferromagnetic shielding layer; and
a layer of silicone adhesive that attaches the ferromagnetic shielding layer to the inner surface.

9. The shielding can defined in claim 8 further comprising an insulating layer, wherein the ferromagnetic shielding layer is interposed between the insulating layer and the metal shielding can structure.

10. The shielding can defined in claim 9 wherein the insulating layer comprises an inorganic material.

11. The shielding can defined in claim 9 wherein the insulating layer comprises an organic material.

12. The shielding can defined in claim 9 further comprising silicone adhesive that attaches the insulating layer to the ferromagnetic shielding layer.

13. The shielding can defined in claim 12 wherein the insulating layer comprises a polymer layer.

14. The shielding can defined in claim 13 wherein the polymer layer is a layer of polyimide.

15. An electronic device, comprising:
a housing;
a display in the housing that has a display layer overlapped by a touch sensor;
a printed circuit mounted in the housing;
an electrical component on the printed circuit; and
a shielding can on the printed circuit that covers the electrical component and shields the touch sensor from electromagnetic interference from the electrical component, wherein the shielding can has a metal shielding can structure with opposing inner and outer surfaces and a magnetic shielding layer on the inner surface.

16. The electronic device defined in claim 15 wherein the magnetic shielding layer comprises a polymer layer.

17. The electronic device defined in claim 16 wherein the magnetic shielding layer comprises a ferromagnetic shielding layer interposed between the polymer layer and the inner surface of the metal shielding can structure.

18. The electronic device defined in claim 17 further comprising:
a layer of silicone adhesive between the ferromagnetic shielding layer and the inner surface.

19. Apparatus, comprising:
a touch sensor;
a substrate;
an electrical component soldered to the substrate; and
a shielding can that is soldered to the substrate and that covers the electrical component, wherein the shielding can comprises a metal layer that has a first surface and an opposing second surface that faces the electrical component, a ferromagnetic shielding layer, and a layer of adhesive that attaches the ferromagnetic shielding layer to the second surface.

20. The apparatus defined in claim 19 further comprising a layer of polymer between the ferromagnetic shielding layer and the electrical component.

21. The apparatus defined in claim 20 further comprising adhesive that attaches the layer of polymer to the ferromagnetic shielding layer.
